(19) United States
(12) Patent Application Publication
(10) Pub. No.: US 2007/0284971 A1
(43) Pub. Date: Dec. 13, 2007

(54) ELECTRONIC DEVICE

(75) Inventors: Kenya SANO, Kanagawa-ken (JP); Naoko Yanase, Kanagawa-ken (JP); Ryoichi Ohara, Kanagawa-ken (JP); Takaaki Yasumoto, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/761,767

(22) Filed: Jun. 12, 2007

(30) Foreign Application Priority Data
Jun. 12, 2006 (JP) 2006-162552

(51) Int. Cl. H01L 41/047

(52) U.S. Cl. 310/364

(57) ABSTRACT

An electronic device includes: a lower electrode; a first piezoelectric film provided on the lower electrode; and an upper electrode provided on the first piezoelectric film. At least one of the lower electrode and the upper electrode is made of an alloy composed primarily of aluminum and doped with at least one element selected from the group consisting of Ni, Co, V, Ta, Mo, W, Ti, Y, and Nd. Alternatively, an electronic device includes: a support substrate; a lower electrode provided on the support substrate; a first piezoelectric film provided on the lower electrode; and an upper electrode provided on the first piezoelectric film. The lower electrode is made of an alloy composed primarily of aluminum and doped with at least one element selected from the group consisting of Ni, Co, V, Ta, Mo, W, Ti, Y, and Nd.

### CROSS-REFERENCE TO RELATED APPLICATIONS

This application is based upon and claims the benefit of priority from the prior Japanese Patent Application No. 2006-162552, filed on Jun. 12, 2006; the entire contents of which are incorporated herein by reference.

### BACKGROUND OF THE INVENTION

1. Field of the Invention

This invention relates to an electronic device, and more particularly to an electronic device having a piezoelectric film such as a film bulk acoustic resonator and a MEMS device.

2. Background Art

Recently, MEMS (Micro-Electro-Mechanical System) devices with an acceleration sensor or a pressure sensor integrated on a silicon substrate, as well as film bulk acoustic resonators (FBARs) or bulk acoustic wave (BAW) devices have been developed, and are promising for practical use.

For example, BAW devices are expected to be installed in RF antenna filters for gigahertzband W-CDMA and duplexers for mobile information terminals. The main part of a BAW device has a structure composed of a piezoelectric film sandwiched by two electrodes. The electrode needs to have low resistance, good flatness, and high degree of orientation. This electrode can be used as a seed layer to improve the orientation of the piezoelectric film made of e.g. aluminum nitride (AlN).

When this electrode is made of metal material such as molybdenum (Mo), tungsten (W), ruthenium (Ru), platinum (Pt), or gold (Au) and used to form a BAW device, its electromechanical coupling coefficient (kt²) or quality factor (Q-value) is often degraded because of high specific resistance and/or low degree of orientation of the metal material. In particular, to fabricate a BAW device for use in high frequency bands over 2 GHz, the electrode and the piezoelectric needs to have a smaller thickness, which affects the characteristics of specific resistance and orientation more significantly. Factors affecting the Q-value at resonance frequency include the elastic loss of the piezoelectric, the elastic loss of the electrode, and the series resistance of the electrode. On the other hand, factors affecting the Q-value at anti-resonance frequency include the elastic loss of the piezoelectric, the elastic loss of the electrode, the conductance of the substrate, and the dielectric loss of the piezoelectric. According to the inventor's analysis of experimental data, the Q-value at resonance frequency is mostly attributed to the series resistance of the lower electrode, whereas the Q-value at anti-resonance frequency is governed by the elastic loss of the piezoelectric. It turns out from these investigations that the increase of the series resistance of the electrode due to the above selection of material causes degradation in Q-value at resonance frequency and greatly affects the characteristics of the film bulk acoustic resonator.

On the other hand, JP 3-276615A discloses ferroelectric capacitor electrodes made of nickel-rich alloys such as aluminum-doped nickel (Ni) alloy and NI—Cr—Al (nickel-chromium-aluminum) alloy.

However, unfortunately, nickel-rich alloys have high specific resistance, and suffer from microcracks due to residual stress, resulting in increased resistance and eventually, disconnection. In contrast, Al (aluminum) is promising for the electrode material of a piezoelectric film because it has low resistance and can be improved in orientation characteristics. However, unfortunately, the melting point of Al is as low as about 660° C., and hence hillocks and voids are likely to occur in the process of forming a piezoelectric film under the influence of thermal hysteresis.

### SUMMARY OF THE INVENTION

According to an aspect of the invention, there is provided an electronic device including: a lower electrode; a first piezoelectric film provided on the lower electrode; and an upper electrode provided on the first piezoelectric film, at least one of the lower electrode and the upper electrode being made of an alloy composed primarily of aluminum and doped with at least one element selected from the group consisting of Ni, Co, V, Ta, Mo, W, Ti, Y, and Nd.

According to an aspect of the invention, there is provided an electronic device including: a support substrate; a lower electrode provided on the support substrate; a first piezoelectric film provided on the lower electrode; and an upper electrode provided on the first piezoelectric film, the lower electrode being made of an alloy composed primarily of aluminum and doped with at least one element selected from the group consisting of Ni, Co, V, Ta, Mo, W, Ti, Y, and Nd.

### BRIEF DESCRIPTION OF THE DRAWINGS

FIG. 1 is a schematic cross-sectional view showing an electronic device according to a first example of the invention.

FIGS. 2A and 2B are a top view and a bottom view of the electronic device of this example, respectively.

FIG. 3 is a schematic cross-sectional view showing an electronic device according to a second example of the invention.

FIG. 4 is a schematic cross-sectional view showing an electronic device according to a first comparative example.

FIG. 5 is a graph showing the relationship between the amount of additive element and hillock formation density for the elements added to the lower electrode.

FIG. 6 is a graph showing the relationship between the amount of additive element and specific resistance for the elements added to the lower electrode.

FIG. 7 is a graph showing the relationship between the full width at half-maximum (FWHM) of the X-ray rocking curves of the piezoelectric film used in the electronic device of the first example and the electromechanical coupling coefficient of this BAW device.

FIGS. 8A to 8C are process cross-sectional views showing a process for manufacturing an electronic device of the first example.

FIG. 9 is a schematic cross-sectional view showing an electronic device according to a third example of the invention.

FIG. 10 is a schematic cross-sectional view showing an electronic device according to a fourth example of the invention.

FIG. 11 is a schematic cross-sectional view showing an electronic device according to a fifth example of the invention.

FIG. 12 is a circuit diagram of a voltage controlled oscillator equipped with the electronic device according to this embodiment.

FIG. 13 is a schematic view showing a mobile phone having the voltage controlled oscillator of FIG. 12.

FIG. 14 is a schematic cross-sectional view showing a variable capacitor according to the embodiment of the invention.

FIG. 15 is a schematic cross-sectional view showing another variable capacitor according to the embodiment of the invention.

### DETAILED DESCRIPTION OF THE INVENTION

An embodiment of the invention will now be described with reference to the drawings.

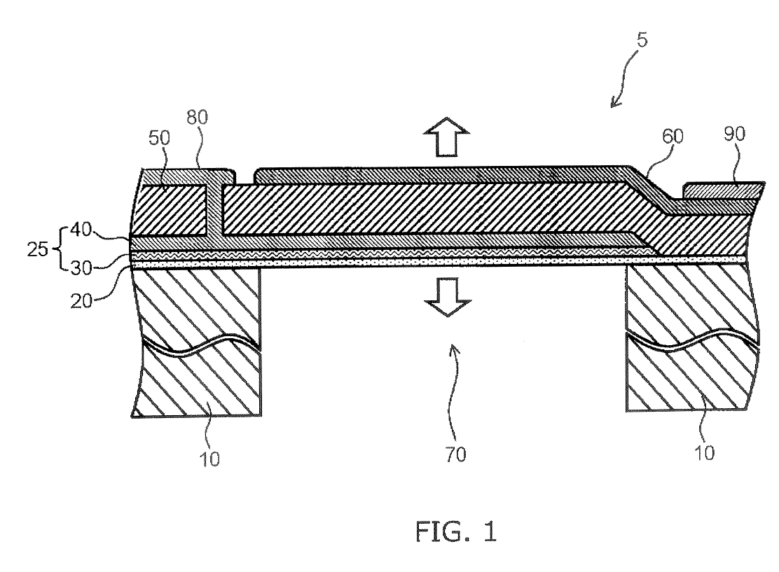

FIG. 1 is a schematic cross-sectional view showing an electronic device according to a first example of the invention.

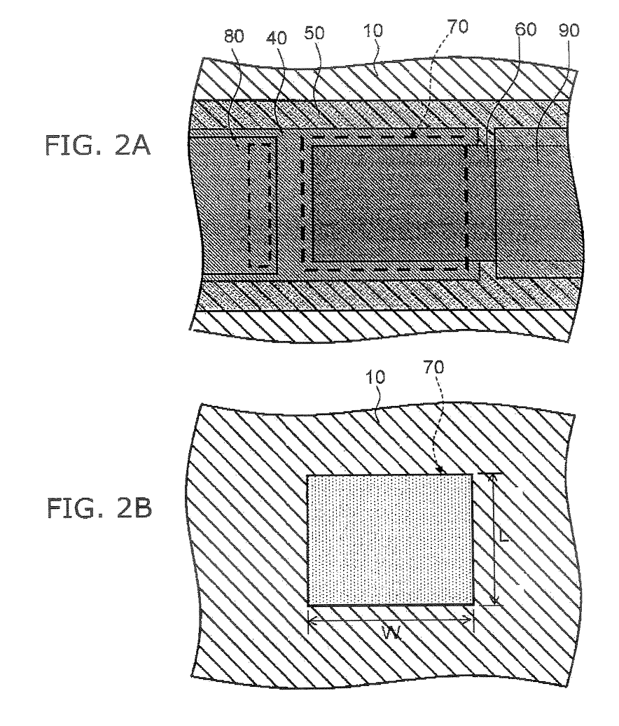

FIGS. 2A and 2B are a top view and a bottom view of the electronic device of this example, respectively. With regard to FIG. 2 and the following figures, elements similar to those described earlier are marked with the same reference numerals and not described in detail.

The electronic device of this embodiment is a film bulk acoustic resonator or bulk acoustic wave (BAW) device 5. This BAW device 5 is formed on a support substrate 10 of e.g. silicon (Si). The support substrate 10 has a hollow portion (cavity) 70. On the entire surface of the support substrate 10 is provided a passivation layer 20 of e.g. thermal oxide film (SiNₓ). A laminated electrode film 25 is provided on the passivation layer 20. The laminated electrode film 25 has a structure in which, for example, an amorphous buffer layer 30 of tantalum aluminum (TaAl) alloy and a lower electrode 40 of aluminum (Al) alloy doped with 4 atomic percent nickel (Ni) element are provided in this order. One end of the laminated electrode film 25 has a surface tapered in accord with the upper electrode 60.

A piezoelectric film 50 of e.g. AlN is provided on the passivation layer 20 and the laminated electrode film 25. An upper electrode 60 made of e.g. molybdenum (Mo) film is selectively provided on the piezoelectric film 50.

A bonding pad 80 made of Al film is provided on the portion of the piezoelectric film 50 not covered with the upper electrode 60. The bonding pad 80 is electrically connected to the lower electrode 40 through a conduction via provided generally perpendicular to the piezoelectric film 50. The bonding pad 80 is spaced from the upper electrode 60 so that the spacing avoids high frequency coupling therebetween at the operating frequency. At the end opposite to the bonding pad 80 across the cavity 70, a bonding pad 90 connected to the upper electrode 60 is formed.

The cavity 70 is provided so that the BAW device 5 vibrating in the thickness direction is not in contact with the support substrate 10. As described later, the cavity 70 may be formed by forming the BAW device 5 on a sacrificial layer and then etching away the sacrificial layer.

The passivation layer 20 serves to prevent the amorphous buffer layer 30 from being oxidized by atmosphere gas and moisture.

The amorphous buffer layer 30 serves to improve wettability with Al by controlling surface energy to enhance the degree of orientation of the lower electrode 40.

The lower electrode 40 of this example comprises 90 to 99.5 atomic percent Al. The other additive is composed of at least one element selected from e.g. Ni, Co, V, Ta, Mo, W, Ti, Y, and Nd. Here the additive is not limited to one kind of additive, but may include a plurality of kinds of additives.

The lower electrode 40 has low specific resistance because it is Al-rich. Thus the loss of the BAW device 5 can be reduced to achieve a high quality factor (Q-value). Furthermore, the lower electrode 40 has high degree of orientation in the <111> direction because it is Al-rich. This lower electrode 40 can be used as a seed layer to obtain a piezoelectric film 50 having good orientation characteristics. Thus the electromechanical coupling coefficient can be increased. Moreover, the lower electrode 40 can be doped with Ni or other element to avoid hillocks and voids to maintain good characteristics of the piezoelectric film 50.

The material of the piezoelectric film 50 is not limited to AlN, but zinc oxide (ZnO) or other materials may also be used.

When a voltage is applied between the lower electrode 40 and the upper electrode 60 of the BAW device 5, the piezoelectric film 50 expands or contracts in the thickness direction. Here, a specific frequency dependence occurs. The thickness of the BAW device 5 can be adjusted to obtain desired frequency characteristics. For example, for a passband frequency of 2 gigahertz, the thickness of the piezoelectric film 50 is 1.5 to 2.0 micrometers. The thickness of the passivation layer 20 is 10 to 100 nanometers. For an input/output impedance of e.g. 50 ohms, the cavity 70 can be shaped like a square or rectangle so that the length L and the width W are about 100 to 200 micrometers, respectively.

As used herein, the near side to the support substrate 10 is referred to as “lower”, and the far side as “upper”.

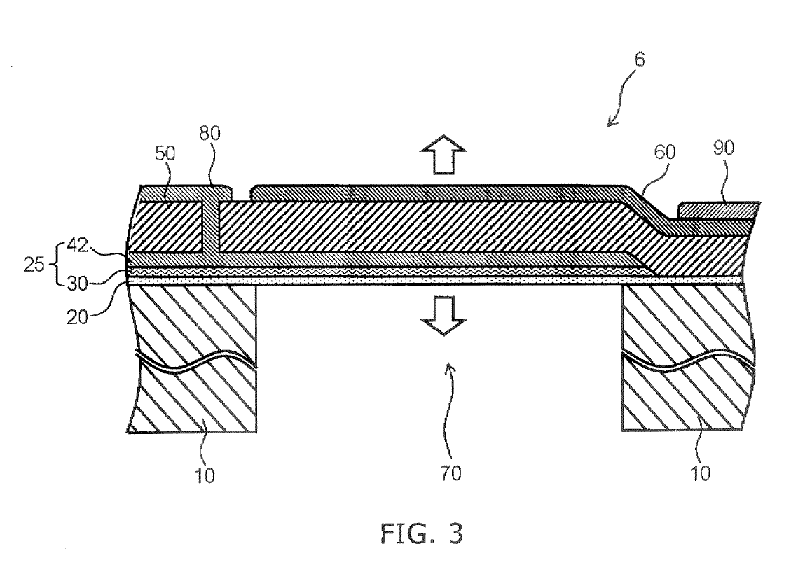

FIG. 3 is a schematic cross-sectional view showing an electronic device according to a second example of the invention.

The electronic device of this example has the same basic structure 6 as described above with reference to FIG. 1, except that the lower electrode 42 is made of Al alloy film doped with 4 atomic percent tantalum (Ta). That is, in this structure, the piezoelectric film 50 is sandwiched between the lower electrode 42 made of Ta-doped Al alloy film and the upper electrode 60 of Mo.

Next, a comparative example to this example is described.

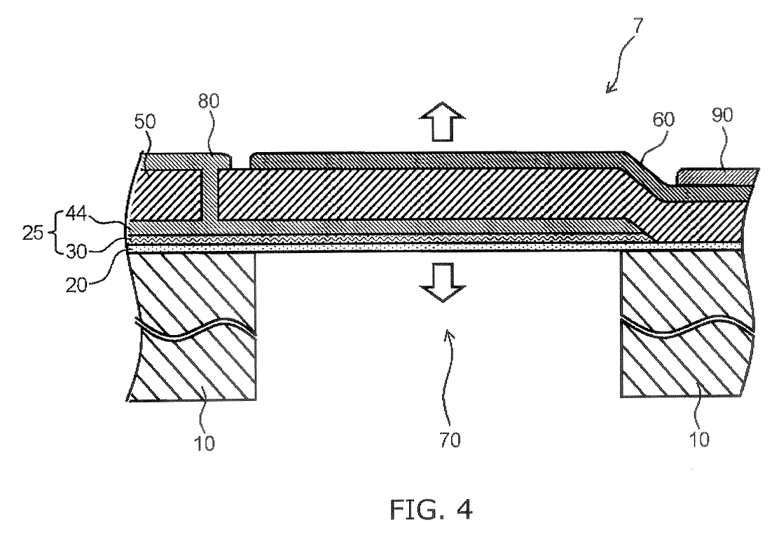

FIG. 4 is a schematic cross-sectional view showing an electronic device according to a first comparative example.

The electronic device of this comparative example is also a BAW device 7. The BAW device 7 of this comparative example has the same basic structure as described above with reference to FIG. 1, except that the lower electrode 44 consists only of Al element. That is, in this structure, the piezoelectric film 50 is sandwiched between the lower electrode 44 made of Al film and the upper electrode 60 made of Mo film.

The characteristics of the above lower electrodes 40, 42, 44 are described with focus on the materials thereof.

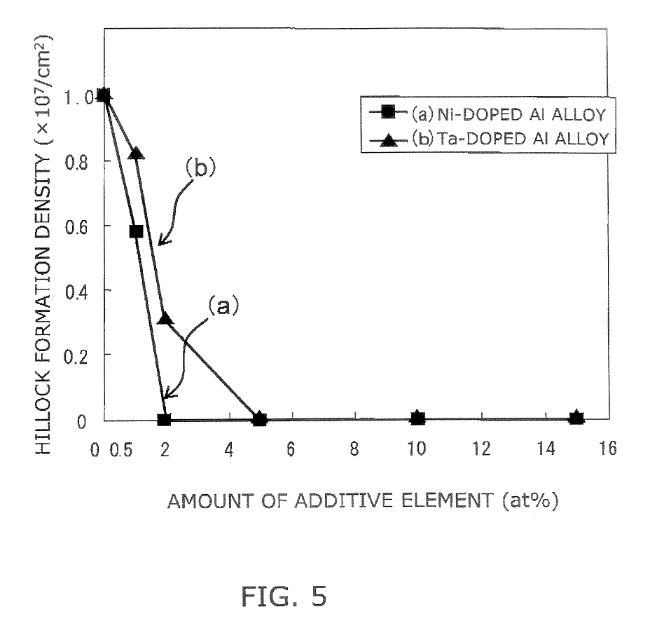

FIG. 5 is a graph showing the relationship between the amount of additive element and hillock formation density for the elements added to the lower electrode. Here the horizontal axis represents the amount of additive element (in atomic percent), and the vertical axis represents hillock formation density (in ×10⁷ hillocks per square centimeter).

The lower electrodes 40, 42, 44 having a thickness of about 200 nanometers were formed by RF sputtering with argon (Ar) gas. Then they were heated to 400° C. for 30 minutes in a vacuum and left alone. The surface of the lower electrode 40, 42, 44 was observed with a Normalski interference microscope to evaluate hillock formation density.

The hillock formation density used herein refers to the number of hillocks per square centimeter. The amount of additive element refers to the amount of additive element contained in the lower electrode 40 except Al.

In the figure, line (a) represents the result for the lower electrode 40 doped with Ni element Line (b) represents the result for the lower electrode 42 doped with Ta element. In these lines (a) and (b), the point at which the amount of additive element is zero represents hillock formation density in the lower electrode 44 consisting only of Al element.

When the amount of additive element is zero, the hillock formation density is as high as about 1×10⁷ per square centimeter. Such a high formation density of hillocks or voids causes the following problems:

(1) The morphology of the electrode is degraded, and “inversion domains” are likely to occur in the piezoelectric film 50 formed thereon. Thus the piezoelectric response to voltage is locally inverted to cancel the piezoelectric effect, decreasing the conversion efficiency.

(2) The electrode thickness locally varies in the area of hillocks and voids. This leads to local variation in frequency and consequently decreases the entire quality factor (Q-value).

Furthermore, the structure of the lower electrode 40, 42, 44 affects the characteristics of the BAW device 5. This is because the structure of the piezoelectric film 50 inherits the structure of the underlying lower electrode 40, 42, 44. For example, the AlN grain size of the piezoelectric film 50 depends on the grain size of the underlying lower electrode 40, 42, 44. More specifically, the structure of the lower electrode 44 consisting only of Al has a large crystal grain size and a few grain boundaries. This structure increases vibration propagating in a direction generally perpendicular to the stretching direction of the piezoelectric film 50 formed thereon, and tends to generate spurious vibration.

In contrast, it is seen from the Ni-doped lower electrode 40 represented by line (a) and the Ta-doped lower electrode 42 represented by line (b) that the hillock formation density significantly decreases with the increase of the amount of additive element.

More specifically, for an added amount of 0.5 atomic percent, the Ni-doped lower electrode 40 has a hillock formation density of about 8×10⁶ per square centimeter, and the Ta-doped lower electrode 42 has a hillock formation density of about 9×10⁶ per square centimeter. It turns out that the hillock formation density nearly equals zero for the addition of Ni at 2 atomic percent or more, or Ta at 5 atomic percent or more.

This is presumably because the following processes result from the addition of Ni or Ta to Al and prevent the occurrence of hillocks:

(1) Solid solution strengthening prevents the expansion of elastic deformation regions or the movement of dislocations.

(2) Alloy precipitation at grain boundaries prevents grain boundary diffusion.

(3) Lattice diffusion of additive element leads to strain relaxation.

For example, reduction of grain boundary diffusion prevents the movement of Al, and hence prevents hillock formation. This also involves prevention of grain growth, which results in a microstructure with a smaller grain size and increased grain boundaries. Then the piezoelectric film 50 has a similar microstructure, which prevents spurious vibration.

Moreover, instead of Ni or Ta, the lower electrode 40 was fabricated with the addition of transition element or rare earth element such as vanadium (V), cobalt (Co), titanium (Ti), molybdenum (Mo), tungsten (W), yttrium (Y), or neodymium (Nd), and it was found that they also have a hillock prevention effect. It is contemplated that the above hillock prevention mechanism may vary to some extent with these different elements. However, it was found that any of these elements has a hillock prevention effect, where addition of V or Co results in a behavior similar to line (a), and addition of the other elements results in a behavior similar to line (b).

Next, a detailed description is given of the electrical characteristics of the lower electrode 40.

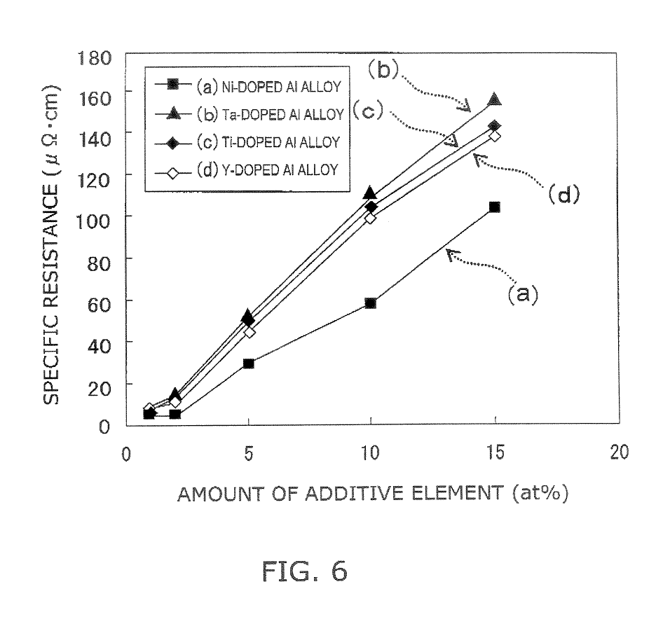

FIG. 6 is a graph showing the relationship between the amount of additive element and specific resistance for the elements added to the lower electrode.

Here the horizontal axis represents the amount of additive element (in atomic percent), and the vertical axis represents specific resistance (in microohm-centimeters). In the figure, lines (a) to (d) represent the result for addition of Ni (lower electrode 40), Ta (lower electrode 42), Ti (lower electrode 41), and Y (lower electrode 43), respectively.

The lower electrodes 40, 41, 42, 43 having a thickness of about 200 nanometers were formed by RF sputtering with argon (Ar) gas. At this time, no heat treatment is applied during and after deposition.

The term “amount of additive element” used herein refers to the amount of additive element contained in the lower electrode 40 except Al. It is seen from FIG. 6 that the amount of additive element is nearly directly proportional to specific resistance in all of the lower electrodes 40, 41, 42, 43. For any amount of additive element, specific resistance is lowest for the Ni-doped lower electrode 40 represented by line (a), and increases in the order of Y represented by line (d), Ti represented by line (c), and Ta represented by line (b).

Assuming that the maximum allowable specific resistance of the BAW device 5 is e.g. 60 microohm-centimeters, any of the lower electrodes 40, 41, 42, 43 can achieve a specific resistance lower than the maximum allowable specific resistance if the amount of additive element is 10 atomic percent or less.

Such elements as V, Co, Mo, W, and Nd were also used instead of the above elements. Consequently, it was found that addition of V or Co results in a behavior similar to line (a), addition of Mo or W is similar to line (b), and addition of Nd is similar to line (d).

The relationship between the electronic state of transition element and the specific resistance of an electrode doped therewith is reported as follows. If a d-orbital of the additive element overlaps the conduction band of Al, virtual bound states occur in the neighborhood of the Fermi level of Al. Thus the specific resistance increases. Furthermore, the partial density of state of d-electrons in the neighborhood of the Fermi level has a good correlation with the specific resistance (J. Phys. F, Metal Phys., 11 (1981) 1787-1800).

For example, in the case of Ni represented by line (a), the partial density of state of d-electrons in the neighborhood of the Fermi level of Al is low, that is, virtual binding of Al conduction electrons is relatively weak. This is presumably responsible for the relatively low specific resistance.

In any of the lower electrodes 40, 41, 42, 43, heat treatment at about 300 to 400° C. results in rapid decrease of resistance due to precipitation of additive element.

As the resistance of the lower electrode 40, 41, 42, 43 increases, the quality factor (Q-value) of the BAW device 5 is degraded. For example, as described later, when a plurality of BAW devices 5 are combined to form a BAW filter, the bandwidth of this filter is proportional to the electromechanical coupling coefficient. On the other hand, the in-band insertion loss is inversely proportional to the figure of merit defined by the product of the electromechanical coupling coefficient and the quality factor. The electromechanical coupling coefficient is specific to the piezoelectric film 50, and may be arbitrary as long as a desired bandwidth can be realized by increasing the crystal purity of the piezoelectric film 50 and aligning the polycrystalline orientation along the polarization direction. Hence the quality factor needs to be maximized for reducing the insertion loss.

In this respect, when the amount of additive element is not less than 0.5 atomic percent and not more than 10 atomic percent, the lower electrode 40, 41, 42, 43 of this example can achieve a specific resistance of 60 microohm-centimeters or less and prevent hillocks and voids. Hence the degradation of the quality factor can be minimized. If the amount of additive element is less than 0.5 atomic percent, the hillock formation density increases as described above with reference to FIG. 5, which shows hillock formation density at 400° C. When the anneal temperature (more directly, the temperature hysteresis of the process) is lower, e.g. 200° C., the hillock prevention effect of additive element is more significant, and the hillock formation density can be reduced close to zero with an added amount of 0.5 atomic percent.

On the other hand, if the amount of additive element is more than 10 atomic percent, the resistance increases and the quality factor is degraded as described above with reference to FIG. 6.

As described above, the characteristics of the BAW device 5 are determined by the electromechanical coupling coefficient and the quality factor. As the electromechanical coupling coefficient increases, the performance of a wideband filter and a voltage controlled oscillator (VCO) is improved. The electromechanical coupling coefficient depends on the film quality of the piezoelectric film 50. That is, it is important to align the crystal polar axis of the piezoelectric film 50 with the film thickness direction, namely, to enhance the degree of orientation. In this respect, the correlation of the electromechanical coupling coefficient with the FWHM value of the X-ray rocking curves of piezoelectric AlN is reported (IEEE Transactions on Ultrasonics, Vol. 47, No. 1 (2000)).

The FWHM value of the X-ray rocking curves of the piezoelectric film 50 can be characterized using the orientation half-width based on X-ray diffraction, for example.

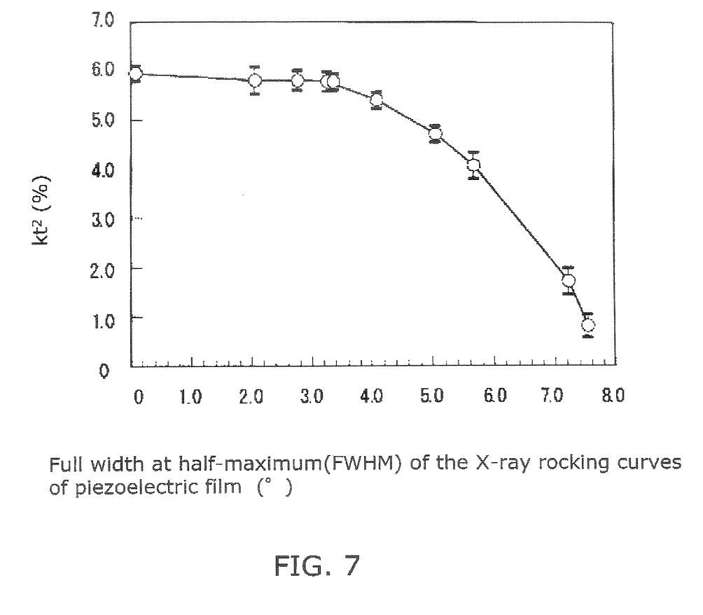

FIG. 7 is a graph showing the relationship between the orientation half-width of the piezoelectric film used in the electronic device of the first example and the electromechanical coupling coefficient of this BAW device.

Here the horizontal axis represents the FWHM value of the X-ray rocking curves (in degree) of the piezoelectric film 50 of AlN, and the vertical axis represents the electromechanical coupling coefficient (in percent). The FWHM value used herein refers to the locking curve of the (0002) X-ray diffraction peak of AlN. In the figure, the electromechanical coupling coefficient is denoted by kt². The piezoelectric film 50 is formed on a Ni-doped lower electrode 40. It is seen from FIG. 7 that the electromechanical coupling coefficient is nearly constant and comparable to the value for single crystals or epitaxial films if the orientation half-width is 4° or less.

The orientation of a piezoelectric film depends on the orientation of the underlying lower electrode. That is, the piezoelectric film 50 inherits the orientation of the lower electrode 40. Thus it turns out that the <111> orientation FWHM value of the lower electrode 40 made of an alloy composed primarily of Al is also preferably 4° or less.

With regard to the Ni-doped lower electrode 40, the inventor verified the relationship between the amount of additive element and the orientation of the lower electrode 40. It was then found that the orientation half-width of the lower electrode 40 can be decreased to 4° or less if the added amount of Ni is reduced to 10 atomic percent or less. Then the orientation of the AlN plezoelectric film 50 formed thereon can also be decreased to 4° or less, and a high electromechanical coupling coefficient is obtained.

Next, various characteristics of the BAW device 5 of the first example and the first comparative example are described below.

The evaluated characteristics include frequency characteristics, electromechanical coupling coefficient, and quality factor. The frequency characteristics were measured using a spectrum analyzer.

In both the first example and the first comparative example, the resonance frequency of the BAW device 5 was 1.9 GHz. The electromechanical coupling coefficient in the first comparative example was 6.3%. In contrast, it was verified that the electromechanical coupling coefficient was increased to 6.9% in the first example. In the first comparative example, the quality factors at resonance (Qr) and anti-resonance (Qa) were 900 and 600, respectively. In contrast, it was found that in the first example, Qr and Qa are 1300 and 1100, respectively, which are higher than in the first comparative example.

As descried above, according to this embodiment, occurrence of hillocks and voids is prevented by adding transition element or rare earth element to the lower electrode 40 composed primarily of Al. Thus the increase of specific resistance is prevented, and a high degree of orientation is maintained, whereas the quality degradation of the piezoelectric film 50 is prevented. Hence a piezoelectric film 50 with high quality can be obtained.

Next, a method for manufacturing an electronic device of the first example according to the invention is described.

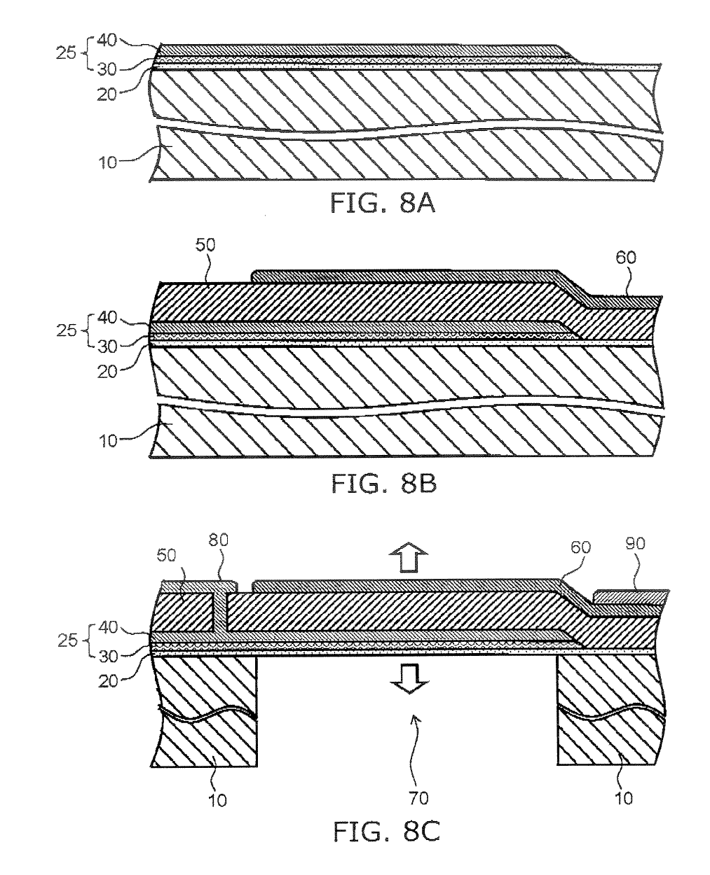

FIGS. 8A to 8C are process cross-sectional views showing a process for manufacturing an electronic device of the first example. This electronic device is a BAW device.

First, as shown in FIG. 8A, on a support substrate 10 of Si having a substrate thickness of about 600 microns, a passivation layer 20 of SiNₓ having a thickness of about 50 nanometers is formed by e.g. low pressure CVD (Chemical Vapor Deposition). A laminated electrode film 25 is continuously formed on the passivation layer 20 by sputtering. The laminated electrode film 25 is composed of, for example, an amorphous buffer layer 30 of tantalum aluminum (TaAl) alloy having a thickness of 10 nanometers and a lower electrode 40 having a thickness of 200 nanometers. The lower electrode 40 is made of aluminum (Al) alloy film doped with 4 atomic percent Ni. A resist mask is patterned on the laminated electrode film 25 using photolithography. Then the laminated electrode film 25 is etched by RIE (Reactive Ion Etching) with chlorine gas, for example. One end of the laminated electrode film 25 is processed to have a surface tapered in accord with the upper electrode 60.

Subsequently, as shown in FIG. 8B, a piezoelectric film 50 of AlN having a thickness of 1.75 micrometers, for example, is formed on the passivation layer 20 and the laminated electrode film 25. The piezoelectric film 50 is formed, for example, by DC pulse sputtering using a mixed gas of argon (Ar) gas and nitrogen (N₂) gas with the substrate temperature being set to about 300° C.

Then a Mo film, for example, having a thickness of 250 nanometers is formed on the piezoelectric film 50. A resist mask is patterned on the Mo film using photolithography. Then an upper electrode 60 of Mo is selectively formed by sputtering. On the piezoelectric film 50, there is also a region where the upper electrode 60 is not formed.

Next, as shown in FIG. 8C, a resist mask is patterned using photolithography on the portion of the piezoelectric film 50 not covered with the upper electrode 60. Then a conduction via is formed generally perpendicular to the major surface of the piezoelectric film 50 by RIE. The conduction via passes through the piezoelectric film 50, and the bottom of the conduction via is located at the lower electrode 40. Furthermore, the conduction via is filled with Al film by sputtering. Subsequently, an Al film is deposited to a thickness of 1 micrometer on the portion of the piezoelectric film 50 not covered with the upper electrode 60. A resist mask is patterned on the Al film using photolithography. Then a bonding pad 80 is formed by RIE, for example. The bonding pad 80 is spaced from the upper electrode 60 so as not to be electrically connected thereto. The bonding pad 80 is connected to the lower electrode 40 through Al filling in the conduction via.

Subsequently, the backside of the support substrate 10 is lapped, and then polished to a thickness of about 200 micrometers. Then a resist mask is patterned thereon by photolithography, for example. Subsequently, the portion of the support substrate 10 below the lower electrode 40 is removed by dry etching using Deep-RIE (Deep Reactive Ion Etching) to form a cavity 70. The etching gas used here may be a combination of sulfur fluoride (SF₆) gas and carbon fluoride (C₄F₈) gas, for example. The SF₆ gas serves to etch the support substrate 10 to form a cavity 70. The C₄F₈ gas serves to form a polymer protective film on the sidewall of the cavity 70. Hence a desired cavity 70 can be produced by alternately supplying these gases. Thus the electronic device of FIG. 1 is completed.

The method for manufacturing an electronic device of the first example according to the invention has been described above.

Next, other examples according to the invention are described.

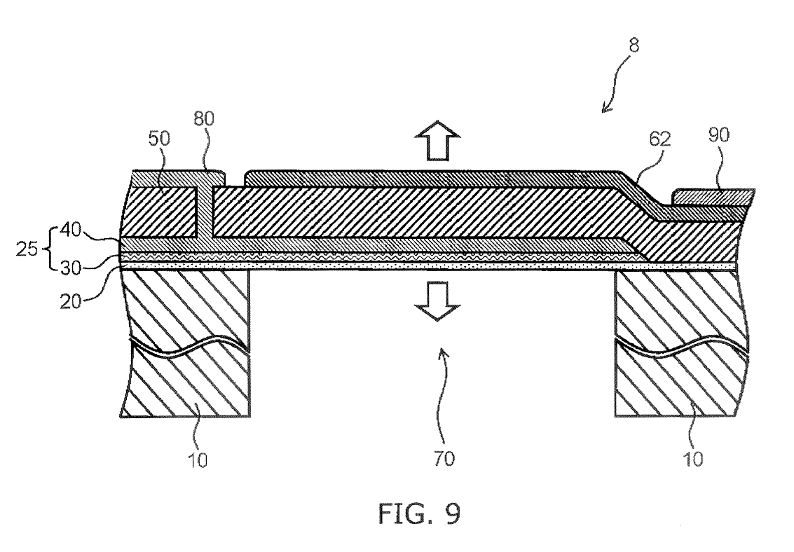

FIG. 9 is a schematic cross-sectional view showing an electronic device according to a third example of the invention.

The electronic device of this example is also a BAW device 8. This example has almost the same basic structure as the first example. However, the lower electrode 40 and the upper electrode 62 are made of Al alloy from doped with 4 atomic percent Ni. That is, in the structure of this BAW device 8, the piezoelectric film 50 is sandwiched between the lower electrode 40 and the upper electrode 62 doped with 4 atomic percent Ni. This material can be used also for the upper electrode 62 in this manner to reduce hillocks in the upper electrode 62, thereby preventing the degradation of characteristics. Hence a highly reliable electronic device is obtained.

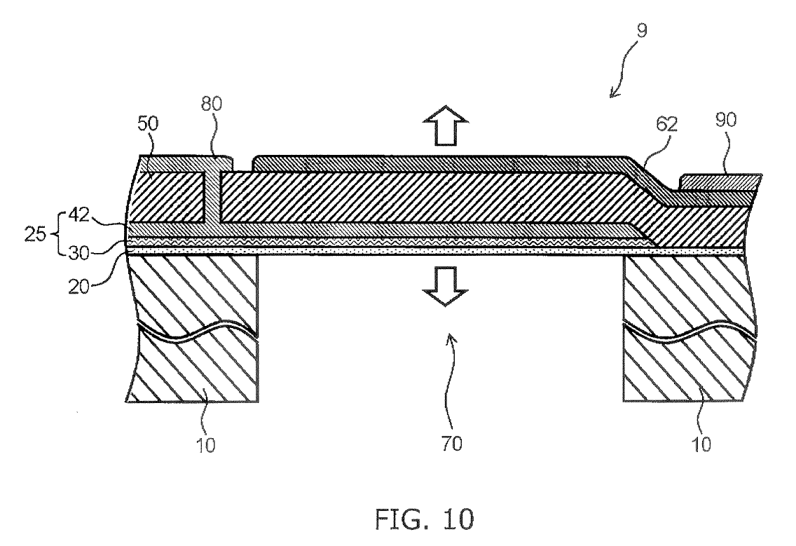

FIG. 10 is a schematic cross-sectional view showing an electronic device according to a fourth example of the invention.

The electronic device of this example is also a BAW device 9. This example has almost the same basic structure as the first example. However, the lower electrode 42 is made of Al alloy doped with 4 atomic percent Ta, and the upper electrode 62 is made of Al alloy doped with 4 atomic percent Ni. That is, in the structure of this electronic device, the piezoelectric film 50 is sandwiched between the lower electrode 42 doped with 4 atomic percent Ta and the upper electrode 62 doped with 4 atomic percent Ni.

Hillocks can be prevented also by using such material for the lower electrode 42. Furthermore, the orientation of the lower electrode 42 can be enhanced in the <111> direction. Hence the orientation of the piezoelectric film 50 can be improved.

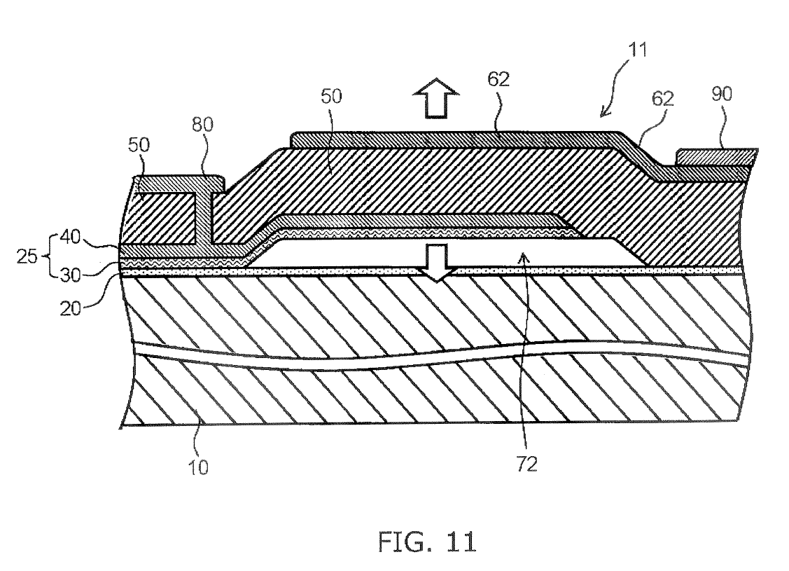

FIG. 11 is a schematic cross-sectional view showing an electronic device according to a fifth example of the invention.

The electronic device of this example is also a BAW device 11. This example has almost the same basic structure as the first example. However, in this structure, a cavity 72 is selectively provided between the passivation layer 20 and the amorphous buffer layer 30.

Also in this structure, because the vibrating portion including the piezoelectric film 50 is not in contact with the support substrate 10, the same effect is achieved as in the first example. Furthermore, this structure does not need to pierce the support substrate 10 by Deep-RIE. Thus the lead time of the manufacturing process can be reduced.

The cavity 72 can be formed as follows.

For example, a sacrificial layer of e.g. silicate glass is formed on the support substrate 10 by CVD. The BAW device 5 is formed as described above on the sacrificial layer and the support substrate 10. Then the sacrificial layer is removed using a wet etchant such as ammonium fluoride (NH₄F) solution to form a cavity 72.

The other examples according to the invention have been described above.

In the BAW device 5, the electric power durability of the electrodes can be increased without forming a fine pattern. Furthermore, the BAW device 5 can be formed on a support substrate 10 of semiconductor. Hence, for example, it is easy to produce an RF filter monolithically. The BAW device 5 of this embodiment can be used to produce a highly efficient BAW filter 100 with good filter characteristics.

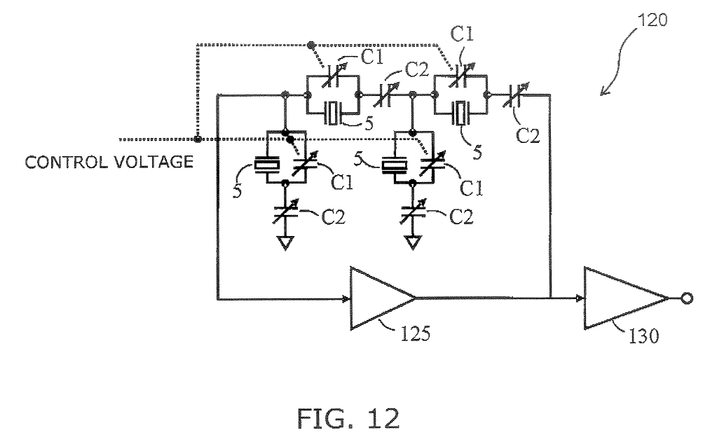

FIG. 12 is a circuit diagram of a voltage controlled oscillator equipped with the electronic device according to this embodiment.

The voltage controlled oscillator (VCO) 120 includes a BAW device 5, an amplifier 125, a buffer amplifier 130, and variable capacitors C1, C2. The frequency component that has passed through the BAW filter 100 is fed back to the input of the amplifier 125, and thereby an output signal is extracted. Hence frequency adjustment is achieved.

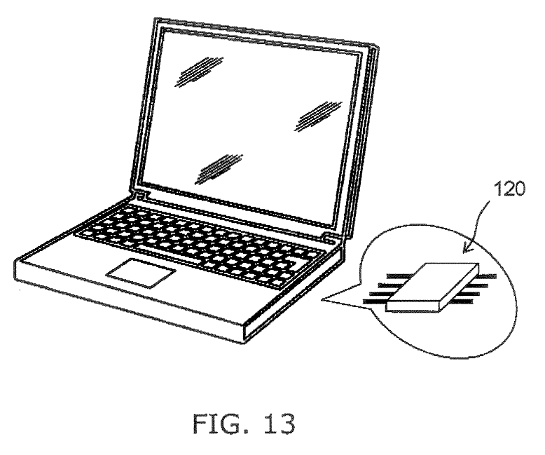

This VCO 120 has a simple configuration, which contributes to downsizing. For example, the VCO 120 is installed on a notebook computer as shown in FIG. 13, and information terminals such as PDA and mobile phone, not shown.

The embodiment of the invention has been described with reference to the examples. However, the invention is not limited to these examples.

More specifically, the electronic device of the examples has been described with reference to a BAW device. However, the examples are not limited thereto, but the effect of the examples can be achieved also in MEMS devices or other electronic devices.

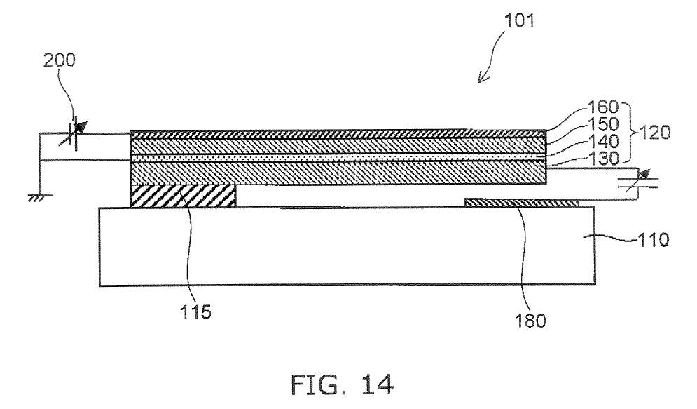

FIG. 14 is a schematic cross-sectional view showing a variable capacitor according to the embodiment of the invention.

In the variable capacitor 101 of this embodiment, one end of a unimorph actuator 120 is supported on a silicon or other support substrate 110 through an anchor 115 made of silicon oxide or the like. The unimorph actuator 120 has a structure in which a silicon support layer 130, a lower electrode 140, a piezoelectric film 150, and an upper electrode 150 are laminated in this order. The lower electrode 140, the piezoelectric film 150, and the upper electrode 160 can be made of various materials described above with reference to FIGS. 1 to 13. The silicon support layer 130 is preferably doped with impurities for decreasing its resistivity.

An opposite electrode 180 is formed on the upper surface of the support substrate 110 opposed to the unimorph actuator 120. The opposite electrode 180 can be formed from a metal having low resistivity such as tungsten or aluminum. A film of insulator may be formed on the opposite electrode 180.

When a voltage is applied from a voltage source 200 between the lower electrode 140 and the upper electrode 160, the piezoelectric film 150 expands or contracts in the in-plane direction depending on the polarity of the voltage. The stress of this deformation is applied to the silicon support layer 130 and the lower electrode 140 underlying the piezoelectric film 150 and to the upper electrode 160 overlying the piezoelectric film 150. However, because the amount of deformation is different between these layers underlying and overlying the piezoelectric film 150, the unimorph actuator is warped upward or downward with the anchor 115 serving as a support point. This deformation results in the variation of spacing between the silicon support layer 130 and the opposite electrode 180, and hence the capacitance therebetween can be varied.

In the unimorph actuator, as the materials of the lower electrode 140 and the upper electrode 160 become softer, the amount of displacement is increased, and the amount of variation in capacitance can be also increased. Furthermore, as the electric resistance of the lower electrode 140 and the upper electrode 160 becomes lower, loss due to the resistance of the electrodes can be reduced, and a highly efficient variable capacitor is obtained. In this respect, according to this embodiment, the lower electrode 140 and the upper electrode 160 are made of an alloy composed primarily of aluminum and doped with at least one element selected from the group consisting of Ni, Co, V, Ta, MO, W, Ti, Y, and Nd. This alloy allows a large amount of displacement because of its softness, and also has low electric resistance. Consequently, a highly efficient variable capacitor can be realized.

In comparison with the bimorph actuator described below, the unimorph actuator of this embodiment is advantageous in its simple structure and ease of manufacturing, despite the small amount of deformation.

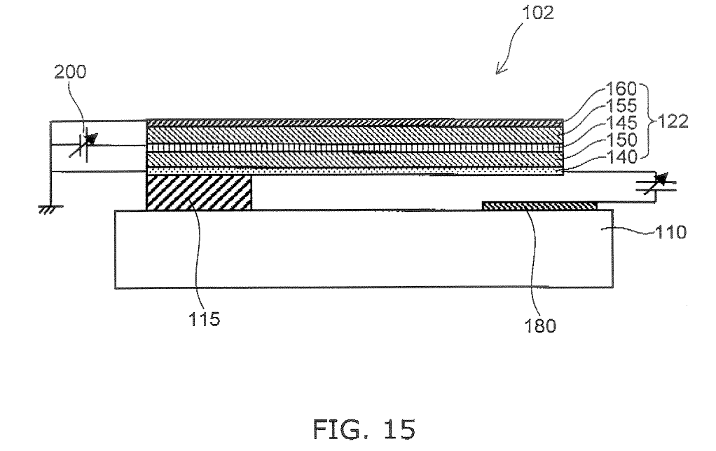

FIG. 15 is a schematic cross-sectional view showing another variable capacitor according to the embodiment of the invention.

In the variable capacitor 102 of this embodiment, one end of a bimorph actuator 122 is supported on a silicon or other support substrate 110 through an anchor 115 made of silicon oxide or the like. The bimorph actuator 122 has a structure in which a lower electrode 140, a first piezoelectric film 150, an intermediate electrode 145, a second piezoelectric film 155, and an upper electrode 160 are laminated in this order. The lower electrode 140, the first piezoelectric film 150, the intermediate electrode 145, the second piezoelectric film 155, and the upper electrode 160 can be made of various materials described above with reference to FIGS. 1 to 13. In the case where the material of the intermediate electrode 145 is same as the material of the lower electrode 140, hillock formation is suppressed and resistance of the electrode can be kept low as described with regard to FIGS. 5 and 6.

When a voltage is applied from a voltage source 200 to the lower electrode 140 and the upper electrode 160 with the intermediate electrode 145 being in the same polarity, opposite voltages are applied to the first piezoelectric film 150 and the second piezoelectric film 155. Then one of the first piezoelectric film 150 and the second piezoelectric film 155 expands, and the other contracts, in the in-plane direction. As a result, about twice the amount of deformation is obtained in comparison with the unimorph actuator described above with reference to FIG. 14.

That is, the spacing between the lower electrode 140 and the opposite electrode 180 varies more greatly, and the capacitance therebetween can be varied more greatly.

Also in the bimorph actuator, as the materials of the lower electrode 140, the intermediate electrode 145, and the upper electrode 160 become softer, the amount of displacement is increased, and the amount of variation in capacitance can be also increased. Furthermore, as the electric resistance of the lower electrode 140, the intermediate electrode 145, and the upper electrode 160 becomes lower, loss due to the resistance of the electrodes can be reduced, and a highly efficient variable capacitor is obtained. In this respect, according to this embodiment, the lower electrode 140, the intermediate electrode 145, and the upper electrode 160 are made of an alloy composed primarily of aluminum and doped with at least one element selected from the group consisting of Ni, Co, V, Ta, Mo, W, Ti, Y, and Nd. This alloy allows a large amount of displacement because of its softness, and also has low electric resistance. Consequently, a highly efficient variable capacitor can be realized.

While FIGS. 14 and 15 illustrate variable capacitors, the invention is not limited thereto. For example, the invention is also applicable to switches based on unimorph or bimorph actuators. Furthermore, the invention can be also applied to a MEMS gyroscope, piezoelectric MEMS microphone, and piezoelectric MEMS speaker to achieve similar effects.

The electronic devices according to the embodiment have been described with reference to examples. However, for example, any modifications adapted by those skilled in the art are also encompassed within the scope of the invention as long as they include the features of the invention.

In the examples, the support substrate 10 is made of Si. However, it is also possible to use other materials such as gallium arsenide (GaAs), indium phosphide (InP), quartz, glass, or plastics being heat resistant to about 200° C.

In the examples, the passivation layer 20 is made of SiNₓ. However, it is also possible to use other materials such as a SiO₂ film having good smoothness or a composite film of oxide film and silicon nitride film (Si₃N₄). Aluminum oxide (Al₂O₃) can also be used.

The material, composition, shape, pattern, manufacturing process and the like of any elements constituting the electronic device of this invention that are variously adapted by those skilled in the art are also encompassed within the scope of the invention as long as they include the features of the invention.

1. An electronic device comprising:
a lower electrode;
a first piezoelectric film provided on the lower electrode; and
an upper electrode provided on the first piezoelectric film,
at least one of the lower electrode and the upper electrode being made of an alloy composed primarily of aluminum and doped with at least one element selected from the group consisting of Ni, Co, V, Ta, Mo, W, Ti, Y, and Nd.

2. The electronic device according to claim 1, wherein the alloy contains aluminum at 90 to 99.5 atomic percent.

3. The electronic device according to claim 1, wherein the lower electrode is made of the alloy, and is a polycrystal having a <111> orientation half-width of 4 degrees or less.

4. The electronic device according to claim 1, further comprising:
a buffer layer provided below the lower electrode and made of amorphous alloy film.

5. The electronic device according to claim 1, wherein the first piezoelectric film is made of AlN.

6. The electronic device according to claim 1, wherein the lower electrode contains Ni at 2 atomic percent or more.

7. The electronic device according to claim 6, wherein the lower electrode contains Ni at 10 atomic percent or less.

8. The electronic device according to claim 1, wherein the lower electrode contains Ta at 5 atomic percent or more.

9. The electronic device according to claim 8, wherein the lower electrode contains Ta at 10 atomic percent or less.

10. The electronic device according to claim 1, further comprising a support substrate having a hollow portion, wherein at least a part of the lower electrode is provided on the hollow portion.

11. The electronic device according to claim 1, further comprising a support substrate having a hollow portion,
wherein the lower electrode is provided on the support substrate, and cavity is provided between the support substrate and the lower electrode.

12. The electronic device according to claim 1, further comprising:
a support substrate; and
an anchor provided on the support substrate,
wherein one end of the lower electrode is supported on the support substrate through the anchor.

13. The electronic device according to claim 12, further comprising:
an intermediate electrode provided between the first piezoelectric film and the upper electrode; and
a second piezoelectric film provided between the intermediate electrode and the upper electrode.

14. The electronic device according to claim 13, wherein the intermediate electrode is made of the same material as the lower electrode.

15. An electronic device comprising:
a support substrate;
a lower electrode provided on the support substrate;
a first piezoelectric film provided on the lower electrode; and
an upper electrode provided on the first piezoelectric film,
the lower electrode being made of an alloy composed primarily of aluminum and doped with at least one element selected from the group consisting of Ni, Co, V, Ta, Mo, W, Ti, Y, and Nd.

16. The electronic device according to claim 15, wherein the lower electrode is made of the alloy, and is a polycrystal having a <111> orientation half-width of 4 degrees or less.

17. The electronic device according to claim 15, wherein the lower electrode contains Ni at 2 atomic percent or more.

18. The electronic device according to claim 15, wherein the lower electrode contains Ni at 10 atomic percent or less.

19. The electronic device according to claim 15, wherein the lower electrode contains Ta at 5 atomic percent or more

20. The electronic device according to claim 15, wherein the lower electrode contains Ta at 10 atomic percent or less.
